(19) United States
(12) Patent Application Publication
(10) Pub. No.: US 2013/0223025 A1
(43) Pub. Date: Aug. 29, 2013

(54) ELECTRONIC DEVICE

(71) Applicants: Tadaomi Fujieda, Nagano (JP); Takashi Nakamura, Nagano (JP)

(72) Inventors: Tadaomi Fujieda, Nagano (JP); Takashi Nakamura, Nagano (JP)

(73) Assignee: SONY CORPORATION, Tokyo (JP)

(21) Appl. No.: 13/588,100

(22) Filed: Aug. 17, 2012

(30) Foreign Application Priority Data
Aug. 25, 2011 (JP) 2011-183307

(51) Int. Cl. H05K 7/02

(52) U.S. Cl. CPC H05K 7/02
USPC 361/753

(57) ABSTRACT

Provided is an electronic device including a housing, at least a part of which has conductive properties; a substrate on which a heating element is mounted and which has a ground pattern; and a spacer which is located between the housing and the ground pattern and which includes a main body portion having heat insulating properties and a conductive portion which is in contact with the ground pattern and the housing and which conducts current between the ground pattern and the housing.

### BACKGROUND

The present technology relates to an electronic device.

In electronic devices, such as notebook personal computers, mobile phones, portable game machines and digital cameras etc., reductions in size and weight are being achieved while improving performance and functionality. If a component having a high heating value as a result of higher performance and higher functionality is to be installed in an electronic device, it is more and more difficult to take measures to dissipate heat in order to meet demands for reducing the size and the thickness of a housing of the electronic device.

When the heat dissipation measures are not sufficient, the temperature of a part of the housing of the electronic device increases and a heat spot is generated. In order to suppress this type of local temperature increase, an electronic device is known in which a heat dissipation plate is provided between the housing and a substrate on which a heating element is mounted, and an air layer is formed between the heat dissipation plate and the housing (refer to Japanese Patent Application Publication No. JP-A-2010-55642, for example).

### SUMMARY

However, since the known electronic device includes the heat dissipation plate and the air layer between the substrate and the housing, it does not sufficiently meet demands for further reducing the size and the thickness of the housing of the electronic device. Further, in order to avoid heat conduction from a support portion that supports the substrate, there is a constraint in arranging the support portion. This constraint is disadvantageous in terms of further reducing the size and the thickness of the housing of the electronic device. Furthermore, in the known electronic device, a ground connection between the housing and the substrate is not taken into account.

The present technology has been made in light of the above-described circumstances, and provides an electronic device that is capable of heat spot suppression of a housing while establishing a ground connection between the housing and a substrate.

In order to solve the above-described problems, an electronic device includes a housing, a substrate and a spacer. At least a part of the housing has conductive properties. A heating element is mounted on the substrate and the substrate has a ground pattern. The spacer is located between the housing and the ground pattern. The spacer includes a main body portion having a heat insulating properties, and a conductive portion which is in contact with the ground pattern and the housing and which conducts current between the ground pattern and the housing.

With the above-described electronic device, heat spot suppression of the housing is achieved while establishing a ground connection between the housing and the substrate.

### BRIEF DESCRIPTION OF THE DRAWINGS

FIG. 1 is a view showing an example of an electronic device according to a first embodiment;

FIG. 2 is a perspective view showing an example of a substrate mounting structure to mount a substrate on a housing of the electronic device according to the first embodiment;

FIG. 3 is an exploded perspective view showing an example of the substrate mounting structure to mount the substrate on the housing of the electronic device according to the first embodiment;

FIG. 4 is a perspective view of a substrate mounting portion of the housing of the electronic device according to the first embodiment;

FIG. 5 is a perspective view of a spacer according to the first embodiment;

FIG. 6 is a perspective view of a heat insulating component according to the first embodiment;

FIG. 7 is a perspective view of a conductive component according to the first embodiment;

FIG. 8 is a cross-sectional view of the substrate mounting structure to mount the substrate on the housing of the electronic device according to the first embodiment;

FIG. 9A is a perspective view of a modified example of the spacer according to the first embodiment;

FIG. 9B is a perspective view of a modified example of the spacer according to the first embodiment;

FIG. 9C is a perspective view of a modified example of the spacer according to the first embodiment;

FIG. 10 is a graph showing relationships between a thickness of the heat insulating component according to the first embodiment, a hot spot temperature and an IC temperature;

FIG. 11 is a perspective view of a modified example of the spacer according to the first embodiment;

FIG. 12A is a perspective view of a modified example of the conductive component according to the first embodiment;

FIG. 12B is a perspective view of a modified example of the conductive component according to the first embodiment;

FIG. 13A is a perspective view of a modified example of the conductive component according to the first embodiment;

FIG. 13B is a perspective view of a modified example of the conductive component according to the first embodiment;

FIG. 14A is a perspective view of a modified example of the conductive component according to the first embodiment;

FIG. 14B is a perspective view of a modified example of the conductive component according to the first embodiment;

FIG. 15A is a perspective view of a spacer according to a second embodiment;

FIG. 15B is a perspective view of a spacer according to the second embodiment; and

FIG. 16 is a cross-sectional view of a substrate mounting structure to mount the substrate on a housing of an electronic device according to the second embodiment.

### DETAILED DESCRIPTION OF THE EMBODIMENTS

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

Hereinafter, embodiments of the present technology will be explained with reference to the appended drawings.

### First Embodiment

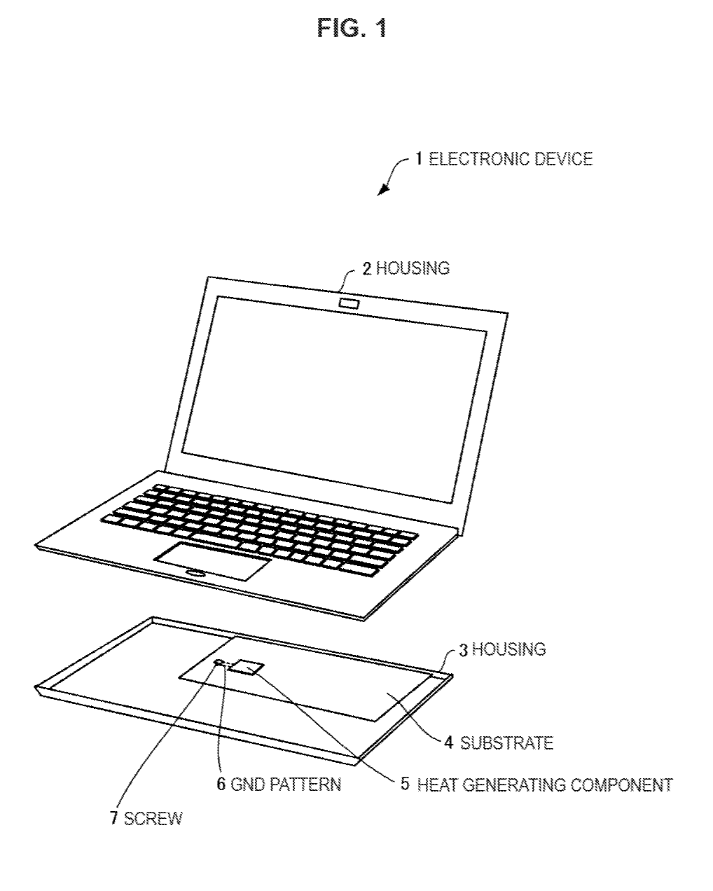

First, an electronic device according to a first embodiment will be explained with reference to FIG. 1. FIG. 1 is a view showing an example of the electronic device according to the first embodiment.

An electronic device 1 is a notebook personal computer which can be folded up and carried around, and into which an input device (for example, a keyboard, a pointing device, a touch panel and the like) and an output device (for example, a liquid crystal display, a speaker and the like) are integrated. In the first embodiment, although the notebook personal computer is shown as an example of the electronic device, it is merely an example. The electronic device may be a non-mobile electronic device, such as a desktop personal computer, as well as a mobile electronic device, such as a mobile phone, a portable game machine, a digital camera or the like.

The electronic device 1 includes a box-type housing 3 that forms a bottom portion, and a housing 2 that is a lid element of the housing 3. The housing 2 includes a user interface, such as an input device, an output device or the like. The housing 3 houses necessary components, such as a substrate 4 and a secondary battery (not shown in the drawings).

At least a part of the housing 3 has conductive properties. For example, the housing 3 is a molded component made of a conductive material, such as a magnesium alloy, a conductive resin or the like, or is a manufactured component made of a conductive material, such as stainless steel, aluminum or the like. Alternatively, the housing 3 may be a housing that is formed such that a molded component or a manufactured component made of resin etc., which is an insulator, is covered by a metal plate or a metal foil, or plating or vapor deposition is performed to impart conductive properties.

In a similar manner to the housing 3, at least a part of the housing 2 has conductive properties. By using the housing 2 and the housing 3 that have the conductive properties, the electronic device 1 inhibits noise discharge from inside the housings and noise intrusion from outside the housings.

A heat generating component 5 (an integrated circuit (IC) or a power transistor, for example) is mounted on the substrate 4. A ground (GND) pattern 6 is provided on a bottom surface (a surface facing the housing 3) of the substrate 4. The substrate 4 is fastened to the housing 3 using a screw 7 via a spacer (not shown in FIG. 1).

Although details will be described later, the spacer is formed of a main body portion having heat insulating properties, and a conductive portion which is in contact with the housing 3 and the GND pattern 6 and which conducts a current between the housing 3 and the GND pattern 6. The main body portion of the spacer suppresses heat conduction from the substrate 4 to the housing 3, and the conductive portion of the spacer establishes a ground connection between the housing 3 and the substrate 4.

In this manner, the electronic device 1 achieves heat spot suppression in the housing 3 while establishing a ground connection between the housing 3 and the substrate 4. For example, when a user operates the electronic device 1 on his/her lap, the heat spot suppression in the housing 3 reduces a feeling of discomfort for the user.

Although an example is shown in which the housing 3 supports the substrate 4, the present technology is not limited to this example. The housing 2 may support the substrate 4. When the user operates the electronic device 1, heat spot suppression in the housing 2 reduces a feeling of discomfort for the user in an operation portion or in a palm rest portion.

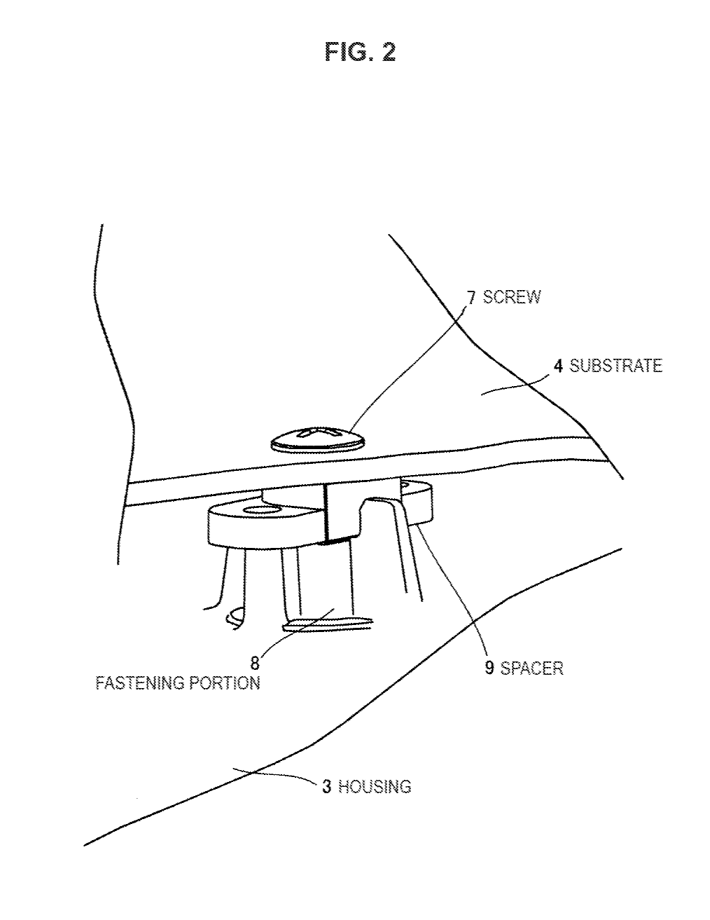

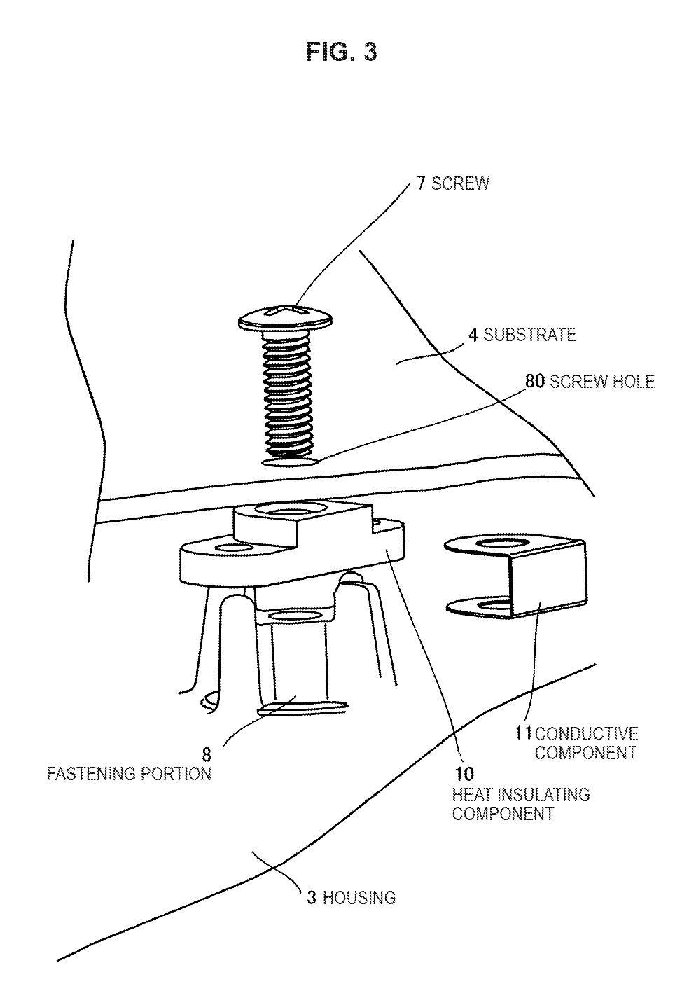

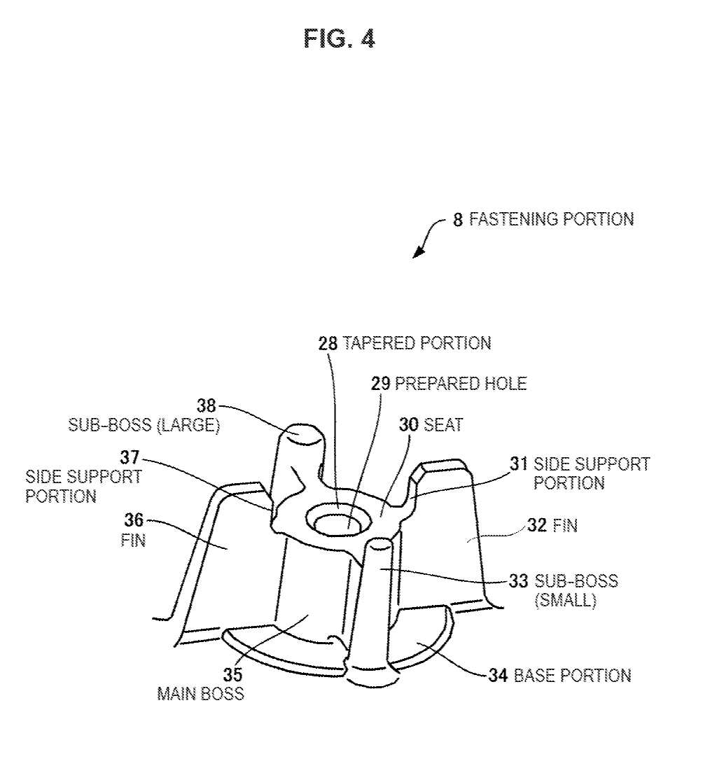

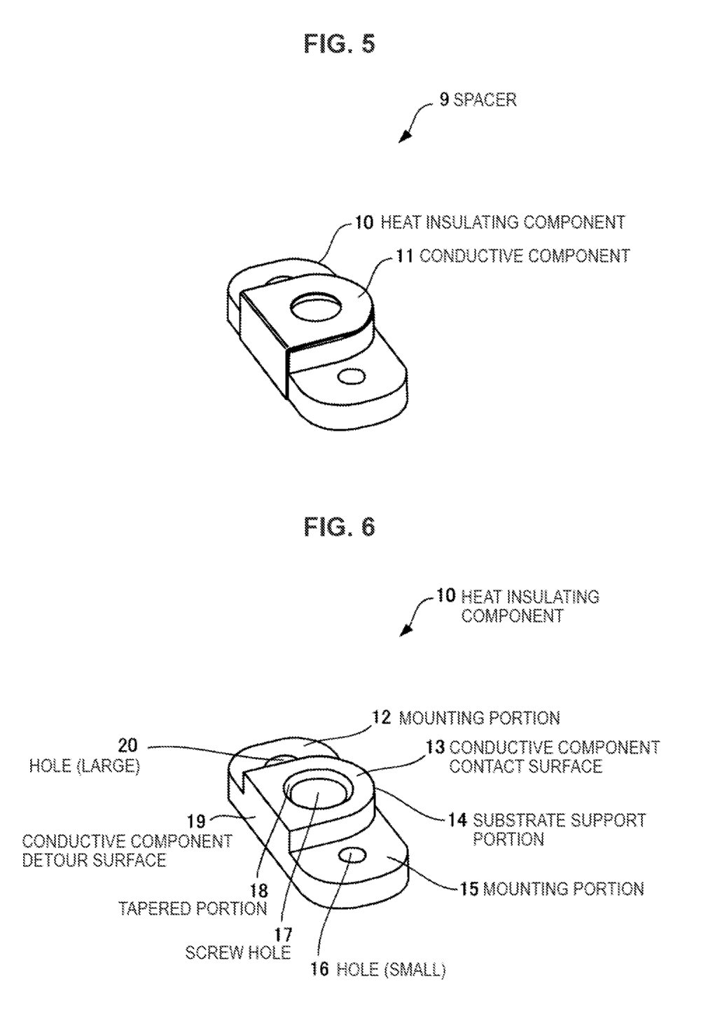

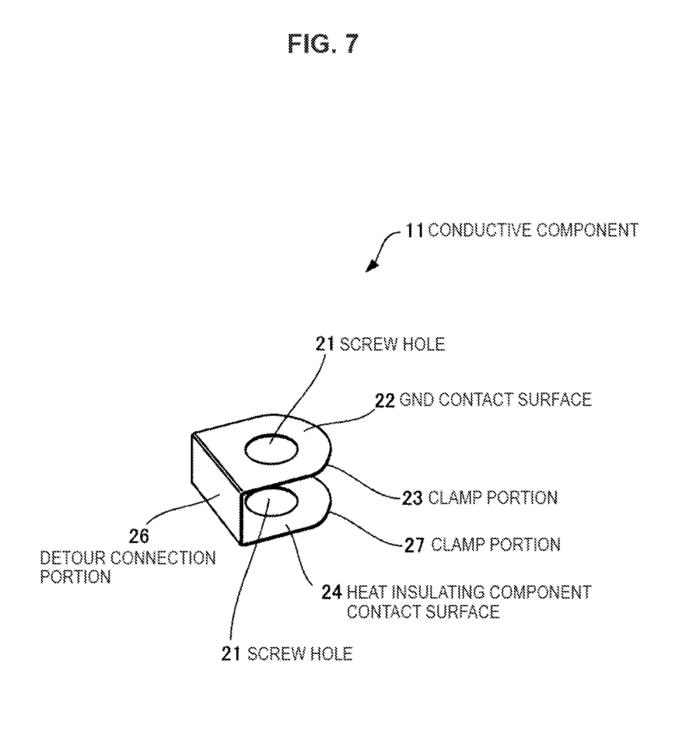

Next, the mounting of the substrate on the housing of the electronic device according to the first embodiment, and structural components will be explained with reference to FIG. 2 to FIG. 7. FIG. 2 is a perspective view showing an example of a substrate mounting structure to mount the substrate on the housing of the electronic device according to the first embodiment. FIG. 3 is an exploded perspective view showing an example of the substrate mounting structure to mount the substrate on the housing of the electronic device according to the first embodiment. FIG. 4 is a perspective view of a substrate mounting portion of the housing of the electronic device according to the first embodiment. FIG. 5 is a perspective view of a spacer according to the first embodiment. FIG. 6 is a perspective view of a heat insulating component according to the first embodiment. FIG. 7 is a perspective view of a conductive component according to the first embodiment.

The housing 3 includes a fastening portion 8 to which the substrate 4 is fastened using the screw 7. The fastening portion 8 rises from a floor surface (a bottom surface) of the housing 3 and supports the substrate 4 via a spacer 9. The fastening portion 8 is a part of the housing 3 and is formed integrally with the housing 3. The fastening portion 8 has conductive properties and is made of a magnesium alloy, for example, in a similar manner to the housing 3.

The fastening portion 8 is provided with a substantially circular base portion 34 that rises from the floor surface by one step. A main boss 35 is provided in a standing condition on the base portion 34 such that the center of the main boss 35 matches the center of the base portion 34. A sub-boss (small) 33, a sub-boss (large) 38, a fin 32 and a fin 36 are provided in a standing condition on the base portion 34 such that they are respectively adjacent to a circumferential surface of the main boss 35 at intervals of 90 degrees and such that they extend between the base portion 34 and the floor surface. The sub-boss (small) 33 and the sub-boss (large) 38 are arranged to face each other with the main boss 35 interposed therebetween. The fin 32 and the fin 36 are arranged to face each other with the main boss 35 interposed therebetween.

An upper surface (a surface facing the substrate 4) of the main boss 35 is used as a seat 30 on which the spacer 9 is placed, and a prepared hole 29 for tapping the screw 7 is provided in a central portion of the main boss 35. The main boss 35 includes a tapered portion 28 on a connection portion between the prepared hole 29 and the seat 30.

The sub-boss (small) 33 is a column-shaped boss that is formed such that its diameter decreases from the lower side (the floor surface) toward the upper side. The height of the sub-boss (small) 33 is larger than that of the main boss 35. The sub-boss (small) 33 is laterally connected to the main boss 35 as far as the height of the main boss 35, and protrudes beyond the seat 30. Thus, the sub-boss (small) 33 is fittingly inserted into a hole (small) 16 of the spacer 9 and guides the spacer 9 to its placement position.

The sub-boss (large) 38 is a column-shaped boss that is formed such that its diameter decreases from the lower side (the floor surface) toward the upper side. The height of the sub-boss (large) 38 is larger than that of the main boss 35. The sub-boss (large) 38 is laterally connected to the main boss 35 as far as the height of the main boss 35, and protrudes beyond the seat 30. Thus, the sub-boss (large) 38 is fittingly inserted into a hole (large) 20 of the spacer 9 and guides the spacer 9 to its placement position. The diameter of the sub-boss (large) 38 is different from that of the sub-boss (small) 33, and thus the orientation of the spacer 9 is uniquely determined when it is placed. The sub-boss (large) 38 has a larger diameter than the sub-boss (small) 33, and this makes it easy to feel for an insertion position of the spacer 9 into the hole (large) 20.

The fin 32 and the fin 36 are thin plates having a substantially trapezoid shape. The fin 32 and the fin 36 are higher than the main boss 35. The fin 32 and the fin 36 are laterally connected to the main boss 35 as far as the height of the main boss 35, and they protrude beyond the seat 30. Thus, the fin 32 supports the spacer 9 from the side by a side support portion 31, and the fin 36 supports the spacer 9 from the side by a side support portion 37.

The sub-boss (small) 33, the sub-boss (large) 38, the fin 32 and the fin 36 increase the cubic volume of the fastening portion 8 and thereby increase the heat capacity. They increase the surface area of the fastening portion 8 and thereby increase the amount of heat dissipation. Thus, the fastening portion 8 suppresses generation of a heat spot in the housing 3 due to the heat conducted from the substrate 4.

The spacer 9 is placed on the seat 30 of the fastening portion 8. The spacer 9 has a predetermined height and is interposed between the fastening portion 8 and the substrate 4, thus providing a predetermined gap between the housing 3 and the substrate 4. The spacer 9 is formed by a heat insulating component 10 having heat insulating properties, and a conductive component 11 having conductive properties. The spacer 9 is formed such that the heat insulating component 10 is fittingly inserted into the conductive component.

The heat insulating component 10 includes a columnar substrate support portion 14 and tongue-shaped mounting portions 12 and 15. The substrate support portion 14 has a bottom surface having a D-shaped contour. The mounting portions 12 and 15 are provided on both sides of the substrate support portion 14 such that they are one step lower than the substrate support portion 14. A surface of the substrate support portion 14 placed on the seat 30 is flush with surfaces of the mounting portions 12 and 15 placed on the seat 30. The heat insulating component 10 has heat insulating properties (for example, a heat conductivity of 0.026 W/m·K or more) and restricts heat conduction from the substrate 4 to the housing 3. For example, a molded component made of acrylonitrile-butadiene-styrene resin (ABS resin) can be used as the heat insulating component 10.

The substrate support portion 14 has a conductive component contact surface 13, which is the bottom surface having a D-shaped contour (the surface facing the substrate 4). The conductive component contact surface 13 comes into contact with the conductive component 11. The substrate support portion 14 is placed on the fastening portion 8 and supports the substrate 4 such that a predetermined gap (which approximately corresponds to the height of the substrate support portion 14) is provided between the fastening portion 8 and the substrate 4. A screw hole 17 is provided in a central portion of the conductive component contact surface 13. The conductive component contact surface 13 includes a tapered portion 18 that is provided on a connection portion between the screw hole 17 and the conductive component contact surface 13. The screw 7 is inserted into the screw hole 17 as well as into a screw hole 80 of the substrate 4 and screw holes 21 of the conductive component 11.

A conductive component detour surface 19 is provided on a flat side surface of the substrate support portion 14. The conductive component detour surface 19 faces a detour connection portion 26 where a ground path of the conductive component 11 takes a detour. The heat insulating component 10 is fittingly inserted into the conductive component 11, from the side of the conductive component detour surface 19.

The mounting portion 12 is provided with the hole (large) 20, and the sub-boss (large) 38 is inserted into the hole (large) 20 when the spacer 9 is placed on the seat 30. The mounting portion 15 is provided with the hole (small) 16 whose diameter is smaller than that of the hole (large) 20. When the spacer 9 is placed on the seat 30, the sub-boss (small) 33 is inserted into the hole (small) 16.

The conductive component 11 has conductive properties and establishes a ground connection between the ground of the substrate 4 and the housing 3. The conductive component 11 is made of a conductive material, which is, for example, a metal such as aluminum, stainless steel or the like. The conductive component 11 has a U-shape, and is formed by twice folding back a thin rectangular plate having round corner portions. The conductive component 11 is formed by a thin plate (having a thickness of 0.1 mm, for example) in order to increase heat resistance.

The conductive component 11 includes clamp portions 23 and 27 that clamp the heat insulating component 10, and the detour connection portion 26 that forms a detouring connection between the clamp portion 23 and the clamp portion 27. The detour connection portion 26 comes into contact with the conductive component detour surface 19, and serves as an abutment portion when the heat insulating component 10 is fittingly inserted into the conductive component 11.

The clamp portions 23 and 27 have a D-shaped contour, and are connected to the contour connection portion 26 at their straight line portions. The clamp portions 23 and have heat insulating component contact surfaces 24 that face each other and that come into contact with the heat insulating component 10. The clamp portions 23 and 27 have GND contact surfaces 22, back surfaces of which are the heat insulating component contact surfaces 24. One of the GND contact surfaces 22 comes into contact with the ground of the substrate 4, and the other of the GND contact surfaces 22 comes into contact with the housing 3. The clamp portions 23 and 27 each have the screw hole 21, into which the screw 7 is inserted.

Note that, although the conductive component 11 that is formed by bending a sheet of thin plate and that has the clamp portions 23 and 27 and the detour connection portion 26 is exemplified, the conductive component 11 may be formed by combining separate components that function as the clamp portions 23 and 27 and as the contour connection portion 26.

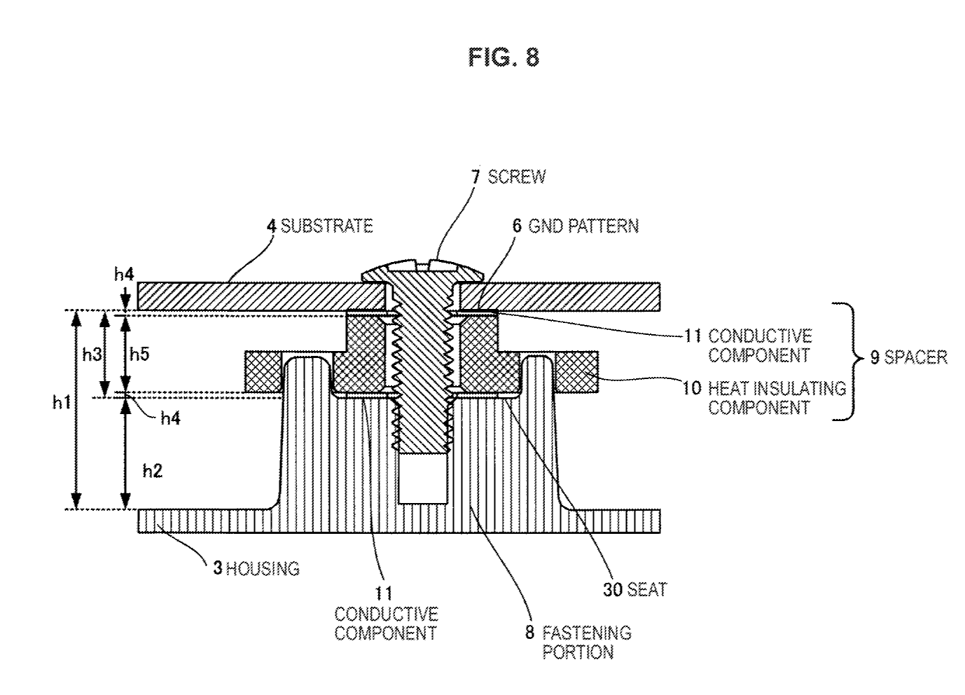

Next, the substrate mounting structure to mount the substrate on the housing of the electronic device according to the first embodiment will be explained using FIG. 8. FIG. 8 is a cross-sectional view of the substrate mounting structure to mount the substrate on the housing of the electronic device according to the first embodiment.

The cross-sectional view shown in FIG. 8 is a cross-sectional view of the substrate mounting structure that is vertically cut from the bottom surface of the substrate 4 at a position passing through the sub-boss (large) 38 and the sub-boss (small) 33, in a state in which the housing 3 supports the substrate 4.

Respectively facing surfaces of the housing 3 and the substrate 4 are separated from each other by a gap having a height h1. The fastening portion 8 includes the seat 30 at a position that rises from the floor surface (the surface of the housing 3 that faces the substrate 4) by a height h2. The spacer 9 having a height h3 is placed on the seat 30. The spacer 9 is formed such that the heat insulating component 10 having a height h5 is fittingly inserted into the conductive component 11 having a plate thickness h4.

A lower surface of the substrate 4 (the surface of the substrate 4 that faces the housing 3) is provided with the GND pattern 6. The GND pattern 6 is in surface contact with one of the GND contact surfaces 22 of the conductive component 11. The other of the GND contract surfaces 22 of the conductive component 11 is in surface contact with the seat 30. Therefore, a current flows between the GND pattern 6 of the substrate 4 and the housing 3 via the conductive component 11, and a ground connection is established. At the same time, the conductive component 11 conducts heat of the substrate 4 to the housing 3.

However, the heat insulating component 10, which serves as the main body of the spacer 9, has heat insulating properties. Therefore, an amount of heat conducted from the substrate 4 to the housing 3 is restricted. In this manner, while the spacer 9 can support the substrate 4, the spacer 9 can restrict the amount of heat conducted from the substrate 4 to the housing 3.

The electronic device 1 uses the fastening portion 8 to receive the heat conducted from the substrate 4 to the housing 3. Therefore, it is possible to reduce a temperature increase by the cubic volume of the fastening portion 8, and to dissipate heat by the surface area of the fastening portion 8.

In this manner, the electronic device 1 achieves heat spot suppression in the housing 3 while establishing a ground connection between the housing 3 and the substrate 4.

Further, when the heat resistance is small, such as when the screw 7 is made of metal, the heat that the screw 7 conducts from the substrate 4 to the housing 3 is not negligible. However, even in this case, the spacer 9 can restrict the amount of heat conducted from the substrate 4 to the housing 3. Note that, when the heat resistance is large, such as when the screw 7 is made of resin, there are cases in which the heat that the screw 7 conducts from the substrate 4 to the housing 3 is negligible.

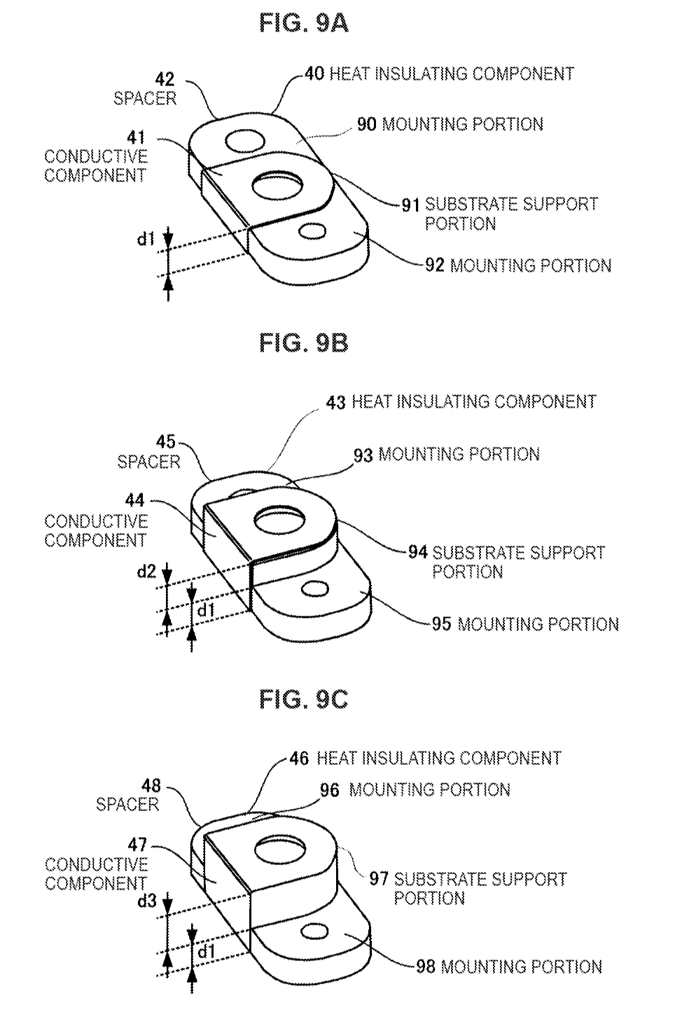

Next, modified examples of the spacer according to the first embodiment will be explained using FIG. 9A to FIG. 9C. FIG. 9A to FIG. 9C are perspective views each showing a modified example of the spacer according to the first embodiment. A spacer 42 shown in FIG. 9A, a spacer 45 shown in FIG. 9B, and a spacer 48 shown in FIG. 9C are common in that the height of mounting portions 90, 92, 93, 95, 96 and 98 is d1.

In the spacer 42, the height of a substrate support portion 91 is the same as the height d1 of the mounting portions 90 and 92. The spacer 42 is formed by a heat insulating component 40 whose height is the same as the height d1 of the substrate support portion 91, and a conductive component 41 whose height corresponds to the height d1 of the substrate support portion 91.

In the spacer 45, the height of a substrate support portion 94 is (d1+d2) that is larger than the height d1 of the mounting portions 93 and 95. The spacer 45 is formed by a heat insulating component 43 whose height is the same as the height (d1+d2) of the substrate support portion 94, and a conductive component 44 whose height corresponds to the height (d1+d2) of the substrate support portion 94.

In the spacer 48, the height of a substrate support portion 97 is (d1+d3) that is larger than the height d1 of the mounting portions 96 and 98. The spacer 48 is formed by a heat insulating component 46 whose height is the same as the height (d1+d3) of the substrate support portion 97, and a conductive component 47 whose height corresponds to the height (d1+d3) of the substrate support portion 97. Note that d3 is larger than d2.

In this manner, in the electronic device 1, the height of the substrate support portion can be set to a given height. If the height of the seat 30, on which the spacer 42, 45 or 48 is placed, is the same, the electronic device 1 can adjust the gap between the housing 3 and the substrate 4 depending on which of the spacers 42, 45 and 48 is used. If the height of the seat 30, on which the spacer 42, 45 or 48 is placed, is changed depending on which of the spacers 42, 45 and 48 is used, the electronic device 1 can have a constant gap between the housing 3 and the substrate 4 while changing the heat insulating performance.

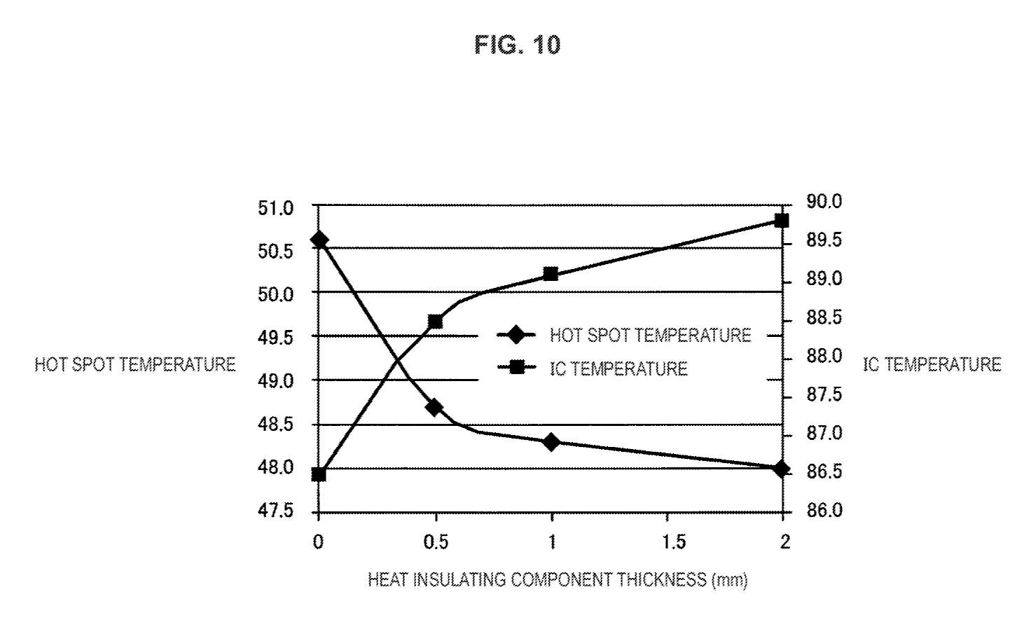

Next, relationships between a thickness (a height) of the heat insulating component according to the first embodiment, a hot spot temperature and an IC temperature will be explained using FIG. 10. FIG. 10 is a graph showing relationships between the thickness of the heat insulating component according to the first embodiment, the hot spot temperature and the IC temperature. Note that Celsius (° C.) is used as the unit of temperature.

The graph shown in FIG. 10 shows the relationship between the hot spot temperature and the IC temperature when the thickness of the heat insulating component (the height of the substrate support portion) is changed, in units of 0.5 mm, from 0 (namely, there is no heat insulating component) to 0.5 mm, 1.0 mm, 1.5 mm and 2.0 mm. The hot spot temperature is the temperature of a location with the highest temperature in the surface temperature distribution of the housing 3. The IC temperature is a surface temperature of the IC, which is a heating element mounted on the substrate 4.

The IC temperature tends to increase as the thickness of the heat insulating component increases. More specifically, it is observed that the IC temperature significantly increases until the thickness of the heat insulating component exceeds 0.5 mm, and after the thickness of the heat insulating component exceeds 0.5 mm, a gentle temperature increase is observed.

On the other hand, the hot spot temperature tends to decrease as the thickness of the heat insulating component increases. More specifically, it is observed that the hot spot temperature significantly decreases until the thickness of the heat insulating component exceeds 0.5 mm, and after the thickness of the heat insulating component exceeds 0.5 mm, a gentle temperature decrease is observed.

In this manner, the IC can suppress a temperature increase by releasing the heat to the housing 3 through the substrate 4. The housing 3 can suppress generation of the hot spot by insulating the substrate 4 from the housing 3.

The spacer provided in the electronic device 1 transfers heat using a conductive component while performing heat insulation using a heat insulating component. Therefore, by appropriately setting the thickness of the heat insulating component, the electronic device 1 can suppress the temperature increase of the IC and suppress the generation of the hot spot, which are conflicting requirements.

In the electronic device 1, it is preferable that the thickness of the heat insulating component that reduces the temperature of the hot spot is set in a range in which the temperature of the IC mounted on the substrate 4 is equal to or less than an operation guarantee temperature. For example, if the operation guarantee temperature of the IC is 89.5 degrees Celsius, the thickness of the heat insulating component of the electronic device 1 can be set to approximately 1.5 mm.

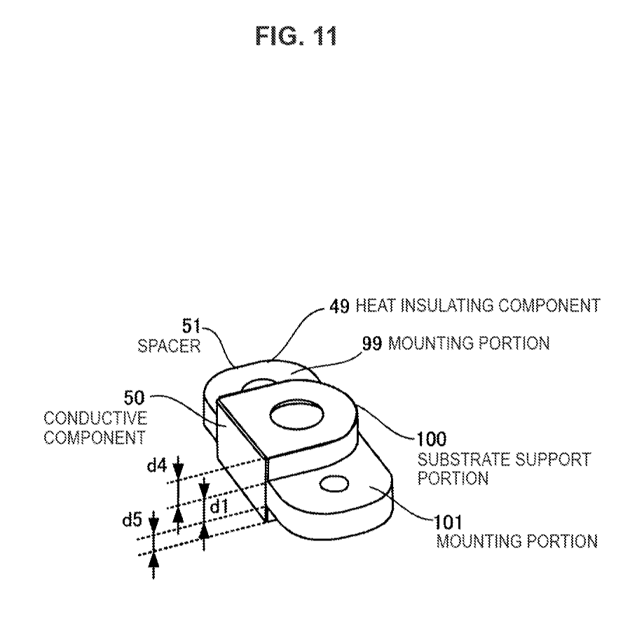

Next, a modified example of the spacer according to the first embodiment will be explained using FIG. 11. FIG. 11 is a perspective view of a modified example of the spacer according to the first embodiment.

A spacer 51 is similar to the above-described spacers 42, 45 and 48 in that the height of mounting portions 99 and 101 is the height d1. In the spacer 51, a substrate support portion 100 protrudes from one surface of the mounting portions 99 and 101 by a height d4, and protrudes from the other surface of the mounting portions 99 and 101 by a height d5. That is, in the spacer 51, the height of the substrate support portion 100 is (d1+d4+d5) that is larger than the height d1 of the mounting portions 99 and 101. The spacer 51 includes a heat insulating component 49 whose height is the same as the height (d1+d4+d5) of the substrate support portion 100, and a conductive component 50 whose height corresponds to the height (d1+d4+d5) of the substrate support portion 100.

Thus, in the electronic device 1, if the height d4 is set to a given value without changing the height of the seat 30, the gap between the housing 3 and the substrate 4 can be adjusted. In addition, in the electronic device 1, if the height d5 is set to a given value without changing the height of the sub-boss (small) 33 and the sub-boss (large) 38, the gap between the housing 3 and the substrate 4 can be made constant while changing the heat insulating performance.

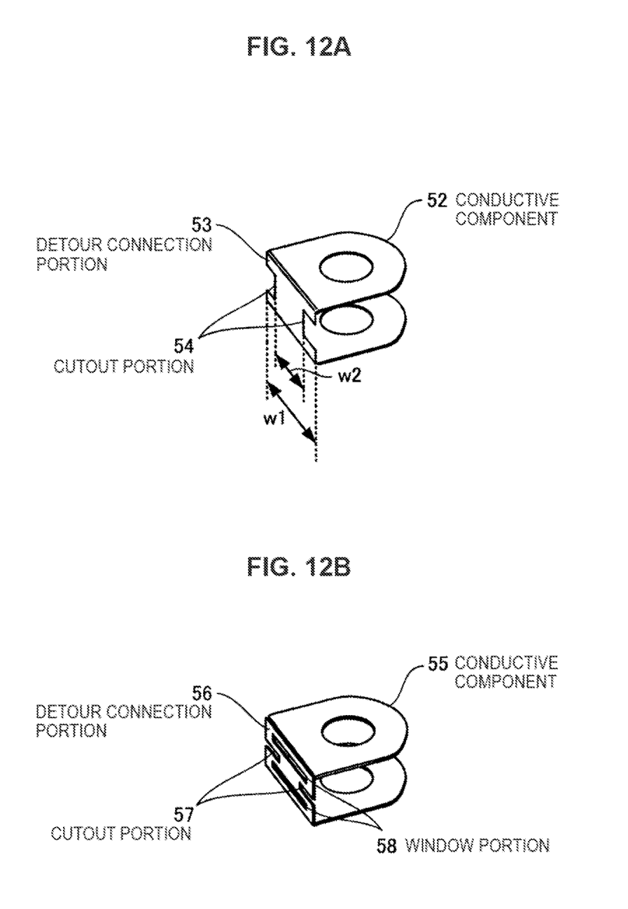

Next, modified examples of the conductive component according to the first embodiment will be explained with reference to FIG. 12A to FIG. 14B. FIG. 12A to FIG. 14B are perspective views of modified examples of the conductive component according to the first embodiment.

A conductive component 52 shown in FIG. 12A includes cutout portions 54 at both sides of a detour connection portion 53. The detour connection portion 53 has a width w1, and a section of the detour connection portion 53 that is cut out by the cutout portions 54 has a width w2 that is smaller than the width w1. Therefore, the heat resistance of the conductive component 52 is increased by the cutout portions 54. In this manner, the heat resistance of the conductive component 52 can be adjusted depending on the width w2 of the section that is cut out by the cutout portions 54.

A conductive component 55 shown in FIG. 12B includes cutout portions 57 at both sides of a detour connection portion 56, and window portions 58 above and below the cutout portions 57. In the detour connection portion 56, the width of a heat conductive path is reduced and the length of the heat conductive path is increased by the cutout portions 57 and the window portions 58. Therefore, the heat resistance of the conductive component 55 increases. In this manner, the heat resistance of the conductive component 55 can be adjusted depending on the width and the length of the heat conductive path in the detour connection portion 56.

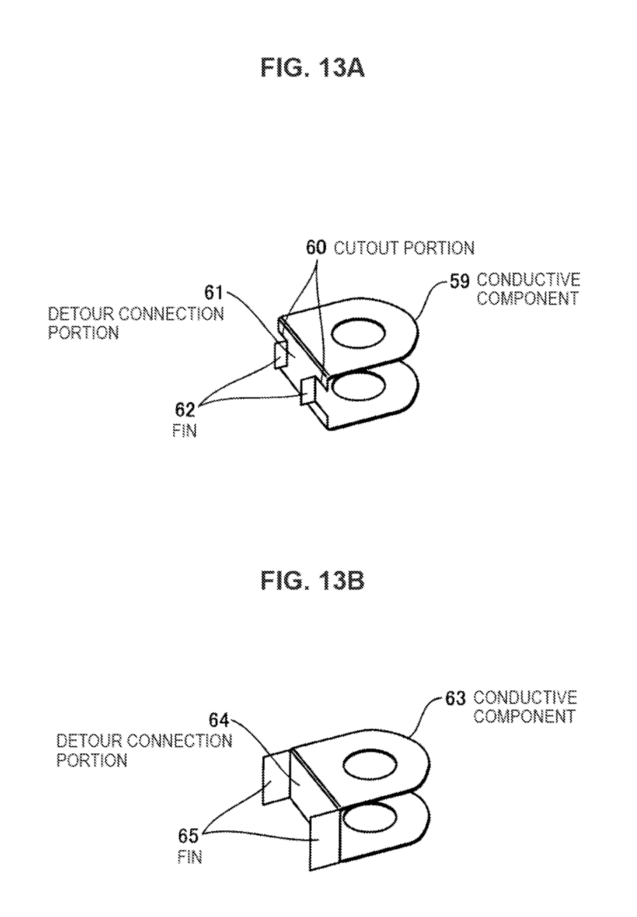

A conductive component 59 shown in FIG. 13A includes cut out portions 60 and fins 62 at both sides of a detour connection portion 61. In the detour connection portion 61, the width of a heat conductive path is reduced by the cutout portions 60. Therefore, the heat resistance of the conductive component 59 increases. In this manner, the heat resistance of the conductive component 59 can be adjusted depending on the width of the heat conductive path in the detour connection portion 61. Further, in the detour connection portion 61, conductive heat is dissipated by the fins 62. In this manner, the conductive component 59 can dissipate heat by an increase in the surface area of the detour connection portion 61.

A conductive component 63 shown in FIG. 13B includes fins 65 at both sides of a detour connection portion 64. In the detour connection portion 64, conductive heat is dissipated by the fins 65. In this manner, the conductive component 63 can dissipate heat by an increase in the surface area of the detour connection portion 64.

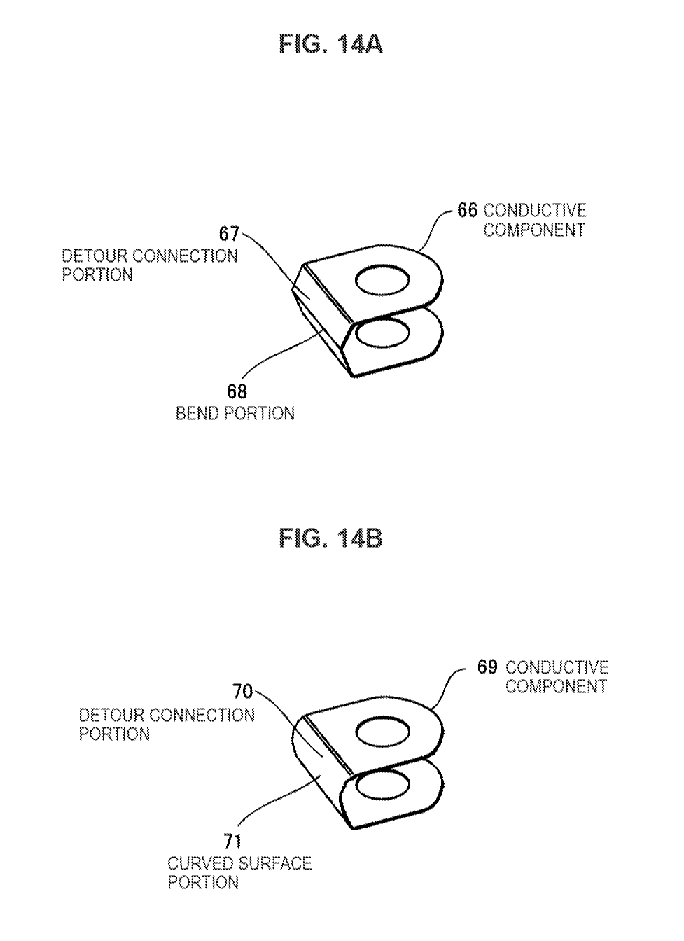

A conductive component 66 shown in FIG. 14A includes a bend portion 68 in a detour connection portion 67. In the detour connection portion 67, the length of a heat conductive path is increased by the bend portion 68. Therefore, the heat resistance of the conductive component 66 increases. In this manner, the heat resistance of the conductive component 66 can be adjusted depending on the length of the heat conductive path in the detour connection portion 67. Further, the detour connection portion 67 is not in contact with a conductive component detour surface of a heat insulating component. Therefore, an air layer is provided between the heat insulating component and the detour connection portion 67, and the heat conducted through the detour connection portion 67 is dissipated. In this manner, the conductive component 66 can dissipate heat by an increase in the area of an air contact surface of the detour connection portion 67.

A conductive component 69 shown in FIG. 14B includes a curved surface portion 71 in a detour connection portion 70. In the detour connection portion 70, the length of a heat conductive path is increased by the curved surface portion 71. Therefore, the heat resistance of the conductive component 69 increases. In this manner, the heat resistance of the conductive component 69 can be adjusted depending on the length of the heat conductive path in the detour connection portion 70. Further, the detour connection portion is not in contact with a conductive component detour surface of a heat insulating component. Therefore, an air layer is provided between the heat insulating component and the detour connection portion 70, and the heat conducted through the detour connection portion 70 is dissipated. In this manner, the conductive component 69 can dissipate heat by an increase in the area of an air contact surface of the detour connection portion 70.

In this manner, in the electronic device 1, the heat resistance and the heat dissipation amount can be set depending on the shape of the conductive component, and the amount of heat conducted from the substrate 4 to the housing 3 can be adjusted.

### Second Embodiment

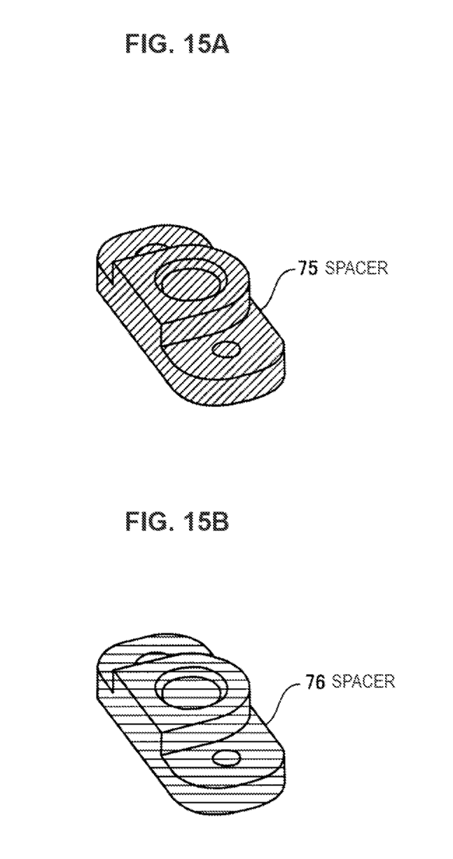

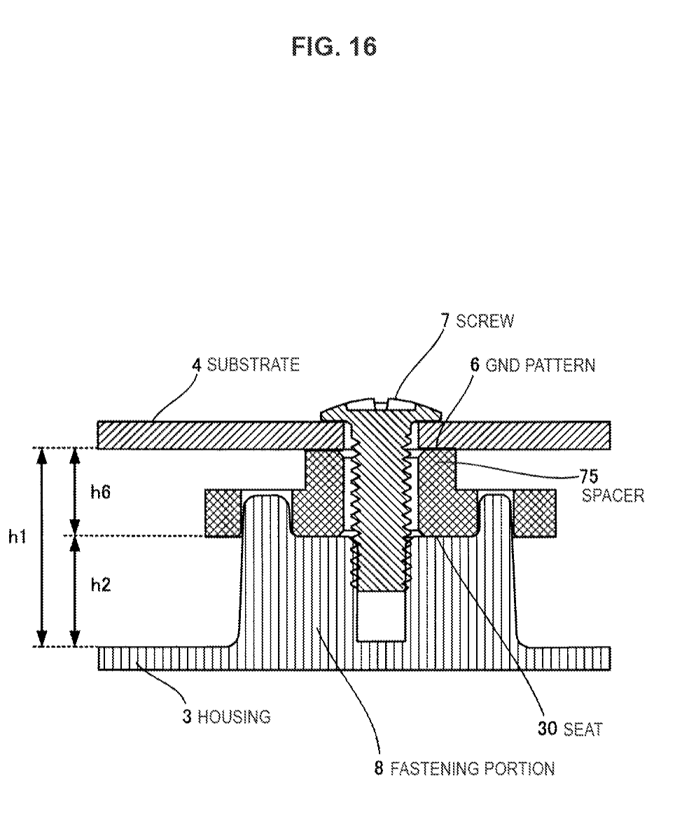

Next, an electronic device according to a second embodiment will be explained using FIG. 15A, FIG. 15B and FIG. 16. FIG. 15A and FIG. 15B are perspective views of spacers according to the second embodiment. FIG. 16 is a cross-sectional view of a substrate mounting structure to mount the substrate on a housing of the electronic device according to the second embodiment. The electronic device of the second embodiment is different from the electronic device of the first embodiment in that conductive processing is performed on a surface of a heat insulating component and a conductive component is not used. Note that, in the explanation of the second embodiment, structural components that are the same as those of the first embodiment are denoted with the same reference numerals and a detailed explanation thereof is omitted.

A spacer 75 shown in FIG. 15A is obtained by performing plating (conductive processing) on a surface of a main body portion having heat insulating properties. For example, chromium plating is performed on the main body portion made of ABS resin. As a result of this, the spacer 75 has both the heat insulating properties and conductive properties.

A spacer 76 shown in FIG. 15B is obtained by performing vapor deposition (conductive processing) on a surface of a main body portion having heat insulating properties. For example, aluminum vapor deposition is performed on the main body portion made of ABS resin. As a result of this, the spacer 76 has both the heat insulating properties and conductive properties.

The cross-sectional view shown in FIG. 16 is a cross-sectional view of the substrate mounting structure that is vertically cut from the bottom surface of the substrate 4 at a position passing through the sub-boss (large) 38 and the sub-boss (small) 33, in a state in which the housing 3 supports the substrate 4.

Respectively facing surfaces of the housing 3 and the substrate 4 are separated from each other by a gap having the height h1. The fastening portion 8 includes the seat 30 at a position that rises from the floor surface (the surface of the housing 3 that faces the substrate 4) by the height h2. The spacer 75 having a height h6 is placed on the seat 30.

The lower surface of the substrate 4 (the surface of the substrate 4 that faces the housing 3) is provided with the GND pattern 6. The GND pattern 6 is in surface contact with the spacer 75. The spacer 75 is in surface contact with the seat 30. Therefore, current flows between the GND pattern 6 of the substrate 4 and the housing 3 via the spacer 75, and a ground connection is established. At the same time, the spacer 75 conducts heat of the substrate 4 to the housing 3.

However, the spacer 75 has heat insulating properties. Therefore, an amount of heat conducted from the substrate 4 to the housing 3 is restricted. In this manner, while the spacer 75 can support the substrate 4, the spacer 75 can restrict the amount of heat conducted from the substrate 4 to the housing 3.

The electronic device 1 uses the fastening portion 8 to receive the heat conducted from the substrate 4 to the housing 3. Therefore, it is possible to reduce a temperature increase by the cubic volume of the fastening portion 8, and to dissipate heat by the surface area of the fastening portion 8.

In this manner, the electronic device 1 achieves heat spot suppression in the housing 3 while establishing a ground connection between the housing 3 and the substrate 4.

Additionally, the present technology may also be configured as below.

(1) An electronic device comprising:

a housing, at least a part of which has conductive properties;

a substrate on which a heating element is mounted and which has a ground pattern; and

a spacer which is located between the housing and the ground pattern and which includes a main body portion having heat insulating properties and a conductive portion which is in contact with the ground pattern and the housing and which conducts current between the ground pattern and the housing.

(2) The electronic device according to (1),

wherein the housing includes a support portion which has conductive properties and which supports the substrate, and

wherein the spacer is provided between the substrate and the support portion.

(3) The electronic device according to (1) or (2),

wherein the spacer is formed by a heat insulating member that is the main body portion, and a conductive member that is the conductive portion.

(4) The electronic device according to (1) or (2),

wherein the spacer has the conductive portion that is formed by performing conductive processing on a surface of a heat insulating member that is the main body portion.

(5) The electronic device according to (3),

wherein the conductive member includes:
a first ground connection portion that is located between the heat insulating member and the ground pattern;
a second ground connection portion that is located between the heat insulating member and the housing; and
a detour connection portion that detours around the heat insulating member and connects the first ground connection portion with the second ground connection portion.

(6) The electronic device according to (5),

wherein the conductive member is formed in a U-shape connecting the first ground connection portion, the second ground connection portion and the detour connection portion.

(7) The electronic device according to (5), wherein the conductive member includes a heat resistance increasing portion in the detour connection portion.

(8) The electronic device according to (5),

wherein the conductive member includes a heat dissipation portion in the detour connection portion.

(9) The electronic device according to any one of (2) to (8),

wherein the housing includes a heat dissipation portion in the support portion.

It should be understood by those skilled in the art that various modifications, combinations, sub-combinations and alterations may occur depending on design requirements and other factors insofar as they are within the scope of the appended claims or the equivalents thereof.

The present disclosure contains subject matter related to that disclosed in Japanese Priority Patent Application JP 2011-183307 filed in the Japan Patent Office on Aug. 25, 2011, the entire content of which is hereby incorporated by reference.

What is claimed is:

1. An electronic device comprising:
a housing, at least a part of which has conductive properties;
a substrate on which a heating element is mounted and which has a ground pattern; and
a spacer which is located between the housing and the ground pattern and which includes a main body portion having heat insulating properties and a conductive portion which is in contact with the ground pattern and the housing and which conducts current between the ground pattern and the housing.

2. The electronic device according to claim 1,
wherein the housing includes a support portion which has conductive properties and which supports the substrate, and
wherein the spacer is provided between the substrate and the support portion.

3. The electronic device according to claim 1,
wherein the spacer is formed by a heat insulating member that is the main body portion, and a conductive member that is the conductive portion.

4. The electronic device according to claim 1,
wherein the spacer has the conductive portion that is formed by performing conductive processing on a surface of a heat insulating member that is the main body portion.

5. The electronic device according to claim 3,
wherein the conductive member includes:
a first ground connection portion that is located between the heat insulating member and the ground pattern;
a second ground connection portion that is located between the heat insulating member and the housing; and
a detour connection portion that detours around the heat insulating member and connects the first ground connection portion with the second ground connection portion.

6. The electronic device according to claim 5,
wherein the conductive member is formed in a U-shape connecting the first ground connection portion, the second ground connection portion and the detour connection portion.

7. The electronic device according to claim 5,
wherein the conductive member includes a heat resistance increasing portion in the detour connection portion.

8. The electronic device according to claim 5,
wherein the conductive member includes a heat dissipation portion in the detour connection portion.

9. The electronic device according to claim 2,
wherein the housing includes a heat dissipation portion in the support portion.
